(19) United States
(12) Patent Application Publication
(10) Pub. No.: US 2004/0113227 A1
(43) Pub. Date: Jun. 17, 2004

(54) Dielectric film, its formation method, semiconductor device using the dielectric film and its production method

(76) Inventors: Masashi Goto, Yokohama-shi (JP); Yukihiko Nakata, Nara-shi (JP); Kazufumi Azuma, Yokohama-shi (JP); Tetsuya Okamoto, Kamakura-shi (JP)

Correspondence Address: GRAYBEAL, JACKSON, HALEY LLP, 155 - 108TH AVENUE NE, SUITE 350, BELLEVUE, WA, 98004-5901, US

(21) Appl. No.: 10/726,870

(22) Filed: Dec. 2, 2003

(30) Foreign Application Priority Data
Dec. 3, 2002 (JP) 2002-351167
Apr. 25, 2003 (JP) 2003-121773
Sep. 1, 2003 (JP) 2003-309332

(51) Int. Cl. H01L 29/00

(52) U.S. Cl. 257/506

(57) ABSTRACT

A high-quality dielectric film is formed by generating plasma of a high electron density by a method such as diluting a rare gas or raising a frequency of a power supplier, and generating oxygen atoms or nitrogen atoms of a high density. The dielectric film contains silicon oxide in which the composition ratio of silicon and oxygen is between (1:1.94) and (1:2) both inclusive, silicon nitride in which the composition ratio of silicon and nitrogen is between (1:1.94) and (1:2) both inclusive, or silicon oxynitride in which the composition ratio of silicon and nitrogen is between (3:3.84) and (3:4) both inclusive.

### BACKGROUND OF THE INVENTION

1. Field of the Invention

The present invention relates to a dielectric film, its formation method, a semiconductor device using the dielectric film, and its production method.

2. Description of Prior Art

As a dielectric film, there are films composed of silicon oxide (SiO₂) or silicon nitride (Si₃N₄). They are used, for example, in a gate dielectric layer of a semiconductor device or a coating layer of a lens. Also, these dielectric films are formed, for example, by a plasma oxidation method (See, e.g., Patent Documents 1 and 2).

[Patent Document 1] Japanese Patent Appln. Public Disclosure No. 11-279773 Official Gazette (pp. 4-7 and FIG. 1)

[Patent Document 1] Japanese Patent Appln. Public Disclosure No. 2001-102581 Official Gazette (pp. 3-5 and FIG. 1)

In the foregoing Patent Documents 1 and 2, densification of plasma and lowering of temperature of plasma for accelerating of formation of a dielectric film and lowering damage to the film are described. According to the method described in the Patent Document 1, however, it is possible to accelerate formation of the dielectric film under an environment of low temperature, but it is not possible to form a dielectric film with good characteristics. Also, according to the foregoing method described in Patent Document 2, another element different from an element constituting the dielectric film is contained, thereby causing a defect in crystalline structure, so that it is not possible to form a fine dielectric film.

Also, in case of using a dielectric film not having a good quality, for example, in a gate dielectric layer of a semiconductor device or coating layer of a lens, it results in degradation in electric characteristics of the semiconductor device (e.g., fall in working speed or reliability) or fall in optical characteristics of the lens (e.g., fall in refractive index). Thus, the quality of a dielectric film affects a great deal electric characteristics of a semiconductor device or optical characteristics of a lens.

### SUMMARY OF THE INVENTION

An object of the present invention is providing a dielectric film with an improved quality and its formation method as well as a semiconductor device using the dielectric film and its production method.

The dielectric film according to the present invention is formed directly or indirectly on at least a part of a glass substrate or a plastic substrate, and contains at least silicon oxide in which the composition ratio of silicon and oxygen is between (1:1.94) and (1:2) both inclusive, or silicon nitride in which the composition ratio of silicon and nitrogen is between (3:3.84) and (3:4) both inclusive, or silicon oxynitride having silicon oxide in which the composition ratio of silicon and oxygen is between (1:1.94) and (1:2) both inclusive or the composition ratio of silicon and nitrogen is between (3:3.84) and (3:4) both inclusive.

A silicon layer or a silicon compound layer is formed directly or indirectly on at least a part of said glass substrate or said plastic substrate, and said dielectric film is formed on at least a part of said silicon layer or said silicon compound layer. According to this, the dielectric film can be formed on a glass substrate with a low heat endurance or a plastic substrate with a low heat endurance.

Said plastic substrate can be made of polyimide resin, polyetherketone resin, polyethersulfone resin, polyetherimide resin, polyethylenenaphthalate resin or polyester resin.

A method of forming a dielectric film according to the present invention is a method of forming said dielectric film and comprises steps of preparing a substrate having in the surface a silicon layer formed directly or indirectly on at least a part of said glass substrate or said plastic substrate; and processing the surface of said silicon layer in plasma with an electron density of 3×10¹¹ cm⁻³ or over, which formed by exciting a gas composed of at least one element constituting said dielectric film.

Preferably, said gas is composed of an oxygen molecule, or a molecular nitrogen or an ammonia molecule.

Preferably, said gas further contains a rare gas element, and the partial pressure of the rare gas element is 90% or over of the total pressure.

Further preferably, said rare gas element is argon, or xenon or krypton.

Still preferably, said gas is an oxygen molecule, said rare gas element is xenon, and the energy of a light generated from said plasma is 8.8 eV or less.

Preferably, a frequency of a power supplier for generating said plasma is 2.45 GHz or over.

Preferably, said glass substrate or said plastic substrate is heated at a temperature between 90° C. and 400° C. both inclusive.

The semiconductor device according to the present invention has a dielectric film containing the above-mentioned silicon oxide, the dielectric film being formed on at least a part of a silicon layer formed directly or indirectly on at least a part of a glass substrate or a plastic substrate. Another semiconductor device according to the present invention has a dielectric film containing said silicon nitride, the said dielectric film being formed on at least a part of a silicon layer formed directly or indirectly on at least a part of a glass substrate or a plastic substrate. Still another semiconductor device according to the present invention has a dielectric film containing said silicon oxynitride, the said dielectric film being on at least a part of a silicon layer formed directly or indirectly on at least a part of a glass substrate or a plastic substrate.

Preferably, said dielectric film constitutes a part of a gate dielectric layer relative to the direction of the thickness of the gage insulating layer.

The dielectric film is formed on at least a part of a silicon layer formed directly or indirectly on at least a part of a glass substrate of a plastic substrate.

As the plastic substrate of the semiconductor device, the resin mentioned above can be used.

The above-mentioned method of producing said semiconductor device according to the present invention comprises steps of preparing a substrate with a silicon layer formed directly or indirectly on at least a part of said glass substrate or said plastic substrate; and processing the surface of said silicon layer in plasma with an electron density of 3×10¹¹ cm⁻³ or over, which formed by exciting a gas composed of at least one element constituting said dielectric film.

Preferably, said gas is composed of an oxygen molecule, or a molecular nitrogen or an ammonia molecule.

Preferably, said gas further contains a rare gas element, wherein the partial pressure of the rare gas element is 90% or over of the total pressure. Further preferably, said rare gas element is argon, or xenon or krypton. Still further, preferably, said gas is an oxygen molecule, said rare gas element is xenon, and the energy of a light generated from the plasma is 8.8 eV or less.

Preferably, a frequency of a power supplier for generating said plasma is 2.45 GHz or over.

Preferably, said glass substrate or said plastic substrate is heated at a temperature between 90° C. and 400° C. both inclusive.

Preferably, said dielectric film constitutes a part of a gate dielectric layer relative to the thickness direction of the gate insulating layer.

According to the present invention, the dielectric film contains silicon oxide in in which the composition ratio of silicon and oxygen is between (1:1.94) and (1:2) both inclusive. This composition ratio is substantially equal to an ideal composition ratio of silicon and oxygen in silicon oxide (SiO₂), that is, the stoichiometric composition ratio, 1:2. Also, another dielectric film contains silicon nitride in which the composition ratio silicon and nitrogen is between (3:3.8) and (3:4) both inclusive, which is substantially equal to an ideal composition ratio, 3:4, of silicon and nitrogen in silicon nitride (Si₃N₄). Still another dielectric film contains silicon oxynitride having at least silicon oxide in which the composition ratio of silicon and oxygen is between (1:1.94) and (1:2) both inclusive or at least silicon nitride in which the composition ratio of silicon and nitrogen is between (3:3.84) and (3:4) both inclusive. The composition ratio of silicon oxide (SiO₂) or silicon nitride (Si₃N₄) is substantially equal to an ideal composition ratio.

Consequently, the dielectric film according to the present invention has a good quality with an extremely low defect density in crystalline structure, and improves the electric characteristics of a semiconductor device with the dielectric film, or the optical characteristics of a lens.

Since the plastic substrate of the above-mentioned resin can be used, it is possible to form the dielectric film on a flexible substrate.

By the formation method of the dielectric film according to the present invention, the surface of the silicon layer is exposed to plasma having an electron density of 3×10¹¹ cm⁻³ or over under an environment where a gas composed of at least one element constituting the dielectric film exists. In the plasma, atoms of the gas element having an atom density of 2×10¹³ cm⁻³ or over (e.g., excited atoms in ionization state) is generated, a reaction of silicon and the excited atoms is promoted, and it is possible to form a dielectric film containing, for example, a silicon oxide film or a silicon nitride film having an ideal composition ratio of silicon and at least one element constituting the dielectric film, that is, a composition ratio substantially equal to the stoichiometric composition ratio.

The dielectric film thus obtained has a high quality with an extremely low defect density in crystalline structure. Consequently, a semiconductor excellent in electric characteristics or a lens excellent in optical characteristics can be realized.

Also, the excited atom density in the plasma is increased with an increase in the electron density in the plasma. In the case of the plasma having an electron density of 3×10¹¹ cm⁻³ or over, the dielectric film with good characteristics can be formed at 400° C. or lower. With an increase in electron density, the dielectric film can be formed at 200° C. or less. Consequently, it is possible to form a dielectric film on a glass substrate which is low in heat endurance or a plastic substrate which is low in heat endurance.

A dielectric film containing silicon oxynitride at least having silicon oxide or silicon nitride whose composition ratio is substantially equal to an ideal composition ratio, or silicon oxide or silicon nitride which has an ideal composition ratio can be formed by making the above-mentioned gas composed of oxygen molecule, or molecular nitrogen or ammonia molecule.

Further making the above-mentioned gas contain a rare gas element and making the partial pressure of the rare gas element 90% or over of the total pressure, a reaction between silicon and at least one element which constitutes the dielectric film can be promoted. The reaction enables a dielectric film containing silicon oxynitride at least having silicon oxide or silicon nitride whose composition ratio is closer to the ideal composition ratio or silicon oxide or silicon nitride which has the ideal composition ratio.

By using the rare gas element of argon, or xenon or krypton, reaction between silicon and at least one element constituting the dielectric film is further promoted.

By using the oxygen gas, the rare gas of xenon, and an energy of a light generated from the plasma is 8.8 eV or less, generation of an electron hole pair caused by the light from the plasma can be prevented within SiO₂ formed by the reaction. Since the band gap energy between a filled band and a conduction band of SiO₂ is 8.8 eV, if a light having an energy of 8.8 eV or over is incident on SiO₂, the electron within the filled band is excited to the conduction band and causes an electron hole pair. Such an electron or a hole of the pair is trapped in defects in crystal structure and change the electric characteristics of the semiconductor device, if the dielectric film is used, for example, as a gate dielectric layer of the semiconductor device.

Plasma having an electron density of 3×10¹¹ cm⁻³ or over can be efficiently generated by using the power supplier with the frequency of 2.45 GHz or over.

By heating the above-mentioned glass substrate or plastic substrate at a temperature between 90° C. and 400° C. both inclusive, it is possible to use a glass substrate having a small heat endurance or a plastic substrate having a small heat endurance.

The semiconductor device according to the present invention has a dielectric film containing silicon oxide (SiO₂) which is formed on a silicon layer and whose composition ratio is substantially equal to the ideal composition ratio. Further, another semiconductor device has a dielectric film containing silicon nitride (Si₃N₄) which is formed on a silicon layer and whose composition ratio is substantially equal to the ideal composition ratio. Further, still another semiconductor has a dielectric film containing silicon oxynitride at least having silicon oxide (SiO₂) or silicon nitride (Si₃N₄) which is formed on a silicon layer and whose composition ratio is substantially equal to the ideal composition ratio.

Thereby, a semiconductor device having a dielectric film containing silicon oxide, or silicon nitride or silicon oxynitride having very low defect densities in crystal structure can be realized to improve the reliability and the electric characteristics of the semiconductor device.

By making the above-mentioned dielectric film constitute a part of the gate dielectric layer relative to the thickness direction, the interface characteristics between the gate insulating layer and the silicon layer is improved, thereby improving the function as the gate insulating layer.

If the dielectric film is formed on at least a part of the silicon layer which is formed directly or indirectly on at least a part of the glass substrate or the plastic substrate, it is possible to form a dielectric film on a glass substrate having a low heat endurance or a plastic substrate having a low heat endurance.

As a plastic substrate of the semiconductor device, it is possible to form a dielectric film on the substrate with flexibility by using the above-mentioned resin.

By the method of producing the semiconductor device according to the present invention, the surface of the silicon layer is exposed to the plasma which mentioned above, and the semiconductor device having the dielectric film containing, for example, the oxide, or the nitride or the oxynitride of silicon whose composition ratio is substantially equal to the ideal composition ratio can be formed.

Thus, the dielectric film can be one containing, for example, the oxide, or the nitride or the oxynitride of silicon which has a very low defect density in crystal structure and which has a composition ratio extremely close to or equal to the ideal composition ratio, so that the quality of the dielectric film can be improved. Consequently, the reliability and the electric characteristics of the semiconductor device can be improved.

By making the gas composed of oxygen molecules, or nitrogen molecular or ammonia molecules, a semiconductor device having a dielectric film containing the same silicon oxide or the same silicon nitride as the above-mentioned one, or silicon oxynitride or silicon nitride can be formed.

Suppose that the gas contains a rare gas element, that the partial pressure of the rare gas element is 90% or over of the total pressure, the rare gas element is argon, or xenon or krypton, and the gas is oxygen molecules. Then, an energy of the light generated from the plasma is 8.8 eV or less, then it is possible to form a semiconductor device having a dielectric film with less change in characteristics due to the trap of electrons or holes.

The plasma equipment can be produced inexpensively and efficiently by using the power supplier with the frequency of 2.45 GHz or over.

By heating the glass substrate or the plastic substrate at a temperature between 90° C. and 400° C. both inclusive, a substrate with small heat endurance similar to the above-mentioned one can be used.

By making the dielectric film constitute a part of a gate dielectric layer relative to the thickness direction of the gate dielectric layer, the function of the gate dielectric layer can be improved the same as the above-mentioned one.

### BRIEF DESCRIPTION OF THE DRAWINGS

In the drawings:

FIG. 1 is a side view schematically showing an embodiment of a plasma processing equipment which can be used for forming the dielectric film according to the present invention.

FIG. 2 is a graph of the thickness of the dielectric film as a function of the partial pressure of Kr gas according to the present invention.

FIG. 3 is a graph of the value of X in SiOₓ dielectric film forming by Kr/O₂ or O₂ plasma as a function of the heating temperature according to the present invention.

FIG. 4 is a graph of the oxygen atom density (a.u.) in the Kr/O₂ plasma as a function of partial pressure of Kr gas in gaseous mixture of Kr and O₂ according to the present invention.

FIG. 5 is a graph of the calculated quantity of the generated oxygen atom as a function of the ratio of partial pressure of Kr gas in gaseous mixture of Kr and O₂ according to the present invention.

FIG. 6 is a graph of the electron density in the plasma as a function of the ratio of partial pressure of Kr gas in gaseous mixture of Kr and O₂ according to the present invention.

FIG. 7 is a graph of the calculated oxygen atom density (a.u.) in the plasma as a function of the ratio of partial pressure of Kr gas in gaseous mixture of Kr and O₂ according to the present invention.

FIG. 8 is the graph of the silicon oxide thickness as a function of the ratio of partial pressure of Kr gas in gaseous mixture of Kr and O₂ according to the present invention.

FIG. 9 is the graph of the interface state density of PECVD films with or without the plasma oxide according to the present invention.

FIG. 10 is the embodiment of the production process step to form the thin film transistor using the present invention.

FIG. 11 is the graph of the infrared absorption spectrum of the plasma oxidation film of silicon using O₂ plasma.

FIG. 12 is the graph of the infrared absorption spectrum of the plasma oxidation film of silicon using Kr/O₂ plasma (Kr/(Kr+O₂)=97%) according to the present invention.

FIG. 13 is the graph of the leak current density of O₂ and Kr/O₂ plasma oxidation films as a function of oxidation temperature according to the present invention.

### PREFERRED EMBODIMENT OF THE INVENTION

An outline will be described before explaining embodiments of the present invention in detail.

In the method of forming a dielectric film on a silicon layer according to the present invention, plasma having an electron density of 3×10¹¹ cm⁻³ or over is generated by exciting a gas composed of oxygen or nitrogen. Thereby, an atomic gas (e.g., excited atoms in ionization state) having an atom density of 2×10¹³ cm⁻³ or over is generated. Under such a plasma environment, a dielectric composed of silicon oxide or silicon nitride, for example, a dielectric film is formed. By using this method, a dielectric film having a fine quality can be formed at high speed at 400° C. or less or even at 200° C. or less.

It is possible to use, in place of the above-mentioned gas, a method of generating an atomic gas (e.g., excited atoms in ionization state) having an atom density of 2×10¹³ cm⁻³ or over, by the method of generating plasma having an electron density of 3×10¹¹ cm⁻³ or over to excite a gaseous body containing a rare gas element and introducing an oxygen or nitrogen to the plasma. In this case, a dielectric film having a fine quality can be formed at high speed at 400° C. or less or even at 200° C. or less.

Thus, a gaseous body composed of a rare gas element is used as a gas for generating plasma, and oxygen or nitrogen is added in it, thereby increasing the electron density in the plasma and increasing a decomposition efficiency of the molecules in the plasma. Particularly, when a mass flow ratio of the rare gas is made 90% or over, the electron density rapidly increases, and the decomposition is more efficient.

When the power supply frequency for generating plasma is increased, the electron density in the plasma increases even if the supply power is the same, and the decomposition efficiency of the molecules in the plasma is increased.

In forming the dielectric film, when the composition ratio of the elements within the dielectric film formed at the substrate temperature of 90° C. or over was analyzed by an X-ray photoelectron spectroscopy (hereinafter to be called “XPS”), an analysis result better than that the silicon oxide whose composition ratio of silicon and oxygen is 1:1.94, and better than the silicon nitride whose composition ratio of silicon and nitrogen is 3:3.84. An semiconductor device using these, for example, such as a thin film transistor is improved in electric characteristics relative to interface state density or leak current in comparison with a conventional semiconductor device, and the electric characteristics do not change with time, so that the reliability is also improved.

Embodiment 1

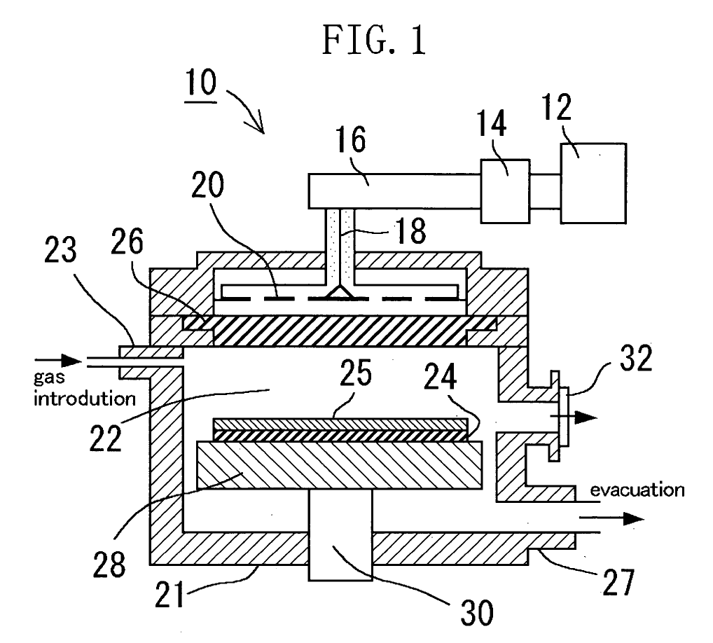

As a plasma processing apparatus for forming a dielectric, for example, a dielectric film, a plasma processing equipment 10, for example, can be used as shown in FIG. 1. The illustrated equipment 10 is provided an electric power unit 12 for microwave generation and a tuner 14 for adjusting the frequency and power of the microwave to generate plasma. That is, with the output end of the electric power unit 12 is connected to a one end side of a wave guide 16, and the tuner 14 is connected at an intermediate portion of the wave guide 16. The other end side of the wave guide 16 is connected to a one end side of a coaxial cable 18. The other end side of the coaxial cable 18 is connected to a radial slot antenna 20 for radiating the microwave power uniformly within a reaction chamber 22. The radial slot antenna 20 having a multiple of slits with a connecting to the coaxial cable 18 at a central portion is substantially equal to the size of a processed substrate 24 or larger than the size of the processed substrate 24.

On the other hand, on a face opposing the radial slot antenna 20, for example, a quartz window 26 made of a material capable of permeating or transmitting the microwave is located. The quartz window 26 is setted air-tightly with O-ring seal, for example, to a top cover of an vaccum chamber 21 for forming a reaction chamber 22. On the side wall faces of the vaccum chamber 21, a gas inlet 23 for introducing a reaction gas is provided above the processed substrate 24, and an evacuating port 27 for evacuating a gas is provided in a position below the processed substrate 24.

The gas inlet 23 is connected to a reaction gas cylinder (not shown) by piping.

The evacuating port 27 is connected to an evacuating pump (not shown) by piping. It is constituted such that, by controlling a evacuating capacity of the evacuating pump, the pressure inside the reaction chamber 22 can be adjusted to a desired pressure value. Further, on a side wall of the vaccum chamber 21, a port 32 is provided to air-tightly insert a probe for the measurement of the electron density in the plasma which is generated inside the reaction chamber 22 or for the measurement of the emission spectrometry.

Further, on a side wall of the vaccum chamber 21, a gate valve (not shown) is provided to open and close when the processed substrate 24 is carried in or out. On the bottom of the reaction chamber 22, a substrate holder 28 is provided to mount the processed substrate 24 which is carried in. This substrate holder 28 has a support shaft at the central portion of substrate holder 28, and the support shaft is connected to a drive unit 30.

The drive unit 30 is provided to move the substrate holder 28 upward and downward. The upward and downward motion is used to set a distance between the quartz window 26 and the processed plate 24 and to deliver the processed substrate 24 in plasma oxidation processing. The plasma generating equipment 10 of a surface wave plasma type is constituted as described above.

The processed substrate 24 is a processed body on whose surface a silicon layer 25 is formed. The processed substrate 24 is, for example, a glass substrate or a plastic substrate.

A microwave with its frequency and electric power controlled by a tuner 14 passes through the coaxial cable 18 and the wave guide 16 and is supplied to a radial line slot antenna (hereinafter to be called “RLSA”) 20 having a dimension of, for example, 264 mm in outer diameter. The microwave supplied to the radial line slot antenna 20 is radiated into the reaction chamber 22 through the quartz window 26, and excites processed gas supplied from the gas inlet 23. As a result, plasma is generated inside the reaction chamber 22 which is kept the desired pressure. It was confirmed that this plasma is in a state of a high electron density called surface wave plasma. The substrate 24 with a silicon layer formed at least in a portion is set to the substrate holder 28 of the reaction chamber 22, such that the silicon layer is opposed to the quartz window 26 at a distance of, for example, 54 mm from the quartz window 26 of the equipment 10.

A window-like port 32 for analysis is provided to be away from the quartz window 26 by a distance of 54 mm like a distance between the substrate 24 and the quartz window 26, and the port 32 is used for measuring an electron density by Langmuir probe and for analysis of luminescence. This enables to obtain measurement results of electron density and analysis results of luminescence corresponding to those obtained on the substrate 24.

The film thickness of a silicon oxide film is measured by an in-situ ellipsometer with the substrate 24 moved to a measuring vessel without breaking the vacuum.

In embodiment 1, a P-type (100) Si single crystal wafer was used as the substrate 24. In this case, the substrate 24 contains the silicon layer 25 in itself. Firstly, after evacuation inside the reaction chamber 22, gas molecules of oxygen and krypton (hereinafter called “Kr”) are introduced until the gas pressure inside the reaction chamber 22 becomes 100 Pa, and the silicon layer 25 was oxidized. The microwave having electric power of 1000 W at a frequency of 2.45 GHz was supplied into the reaction chamber 22. The substrate 24 was heated at a temperature of 300° C. By this oxidation treatment, the silicon layer 25 was oxidized by a surface wave plasma of a high electron density, for example, of 3×10¹¹ cm⁻³ or over generated inside the reaction chamber 22. The time of the oxidation treatment to the silicon layer 25 is four minutes. The thickness of the silicon oxide film formed on the silicon layer 25 was measured.

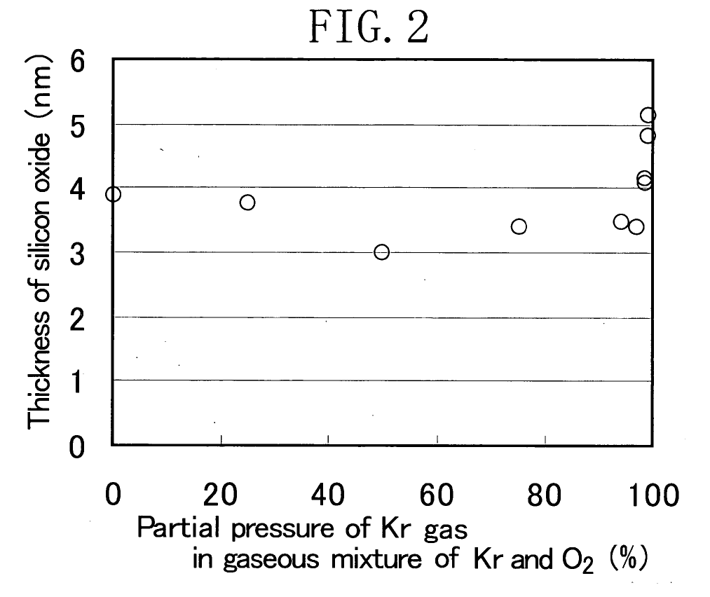

Further, an oxidation treatment of the silicon layer 25 was conducted in the surface wave plasma whose electron density was, for example, 3×10¹¹ cm⁻³ or over and which was composed of a gaseous mixture of Kr and oxygen (O₂), and the thickness of the silicon oxide film formed on the silicon layer 25 was measured. The thickness of the silicon oxide film formed on the surface of the silicon layer 25 was varied as shown in FIG. 2 as a function of the partial pressure of Kr gass in gaseous mixture of Kr and O₂. As shown in FIG. 2, it is understood that the silicon oxide film formed in the surface wave plasma is the thickest at the partial pressure of the Kr gas in the gaseous mixture of Kr and oxygen is about 90% or over.

Next, the frequency and the electric power of the microwave were set on a similar condition which mentioned above, and various silicon oxide films having a thickness of 4 nm were measured. They were formed by oxidizing the silicon layers 25 at various temperatures in the range from 90° C. to 350° C. both inclusive with the two plasma conditions in which the partial pressure ratio of the oxygen gas is 100% (i.e., the environment of oxygen only) and the partial pressure ratio Kr/O₂ is 97%/3%. The composition ratios of silicon and oxygen of the varios silicon oxide films were measured.

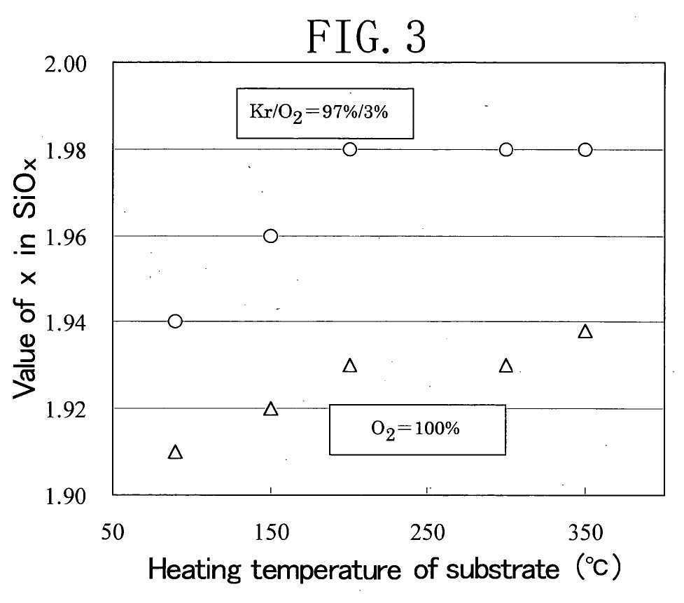

The analysis method to measure the composition ratio of silicon and oxygen is an X-ray photoelectron spectroscopy (hereinafter called “XPS”). The result of analysis is shown as a graph in FIG. 3.

As regards the silicon oxide oxidized in the surface wave plasma wherein the Kr/O₂ is 97%/3% and formed on the surface of the silicon layer 25, while the value of x in the actually formed silicon oxide SiOₓ is about 1.98 when the heating temperature of the substrate 24 is 350° C. The stoichiometric composition ratio of silicon and oxygen in silicon dioxide (SiO₂) is 1:2, and the composition ratio in plasma oxide is very close the stoichiometric composition ratio. This value shows that a silicon oxide film a good composition as SiO₂ was obtained. Also, when the heating temperature of the substrate 24 is 90° C., the value of x is 1.94. This value is also close to the stoichiometric ratio of composition and shows that the composition of the silicon oxide film formed at 90° C. is fine.

Also in the case of the silicon oxide oxidized by the surface wave plasma of oxygen only on the surface of the silicon layer 25, the value of x was between about 1.91 and about 1.94 when the heating temperature of the substrate 24 was between about 90° C. and about 350° C. As shown in FIG. 3, when the oxidation treatment was done by the surface wave plasma in which Kr/O₂ is 97%/3%, the silicon oxide film has a better composition of the film as SiO₂ where the value of x is close to 2.00 than when the oxidation treatment was done by the surface wave plasma in which O₂ is 100%.

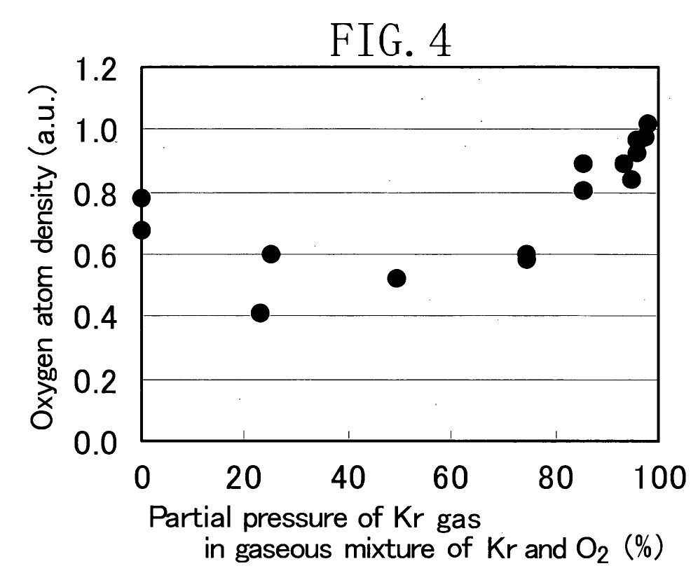

To analyze the cause, the atom density (the unit is an arbitrary unit a.u.) of oxygen is measured by a method known as actinometry. The Ar gas was added to the gaseous body by an amount that partial pressure thereof becomes 1%, and the relative oxygen atom density was obtained from the intensity ratio of two lights, that is, 926 nm light emission of the oxygen atom and 750 nm light emission of Ar. The result is shown as a graph in FIG. 4. As seen from FIG. 4, when the partial pressure of Kr in the gaseous mixture of Kr and O₂ is 90% or over, the oxygen atom rapidly increases to coincide with a trend of variation in the film thickness of the silicon oxide film (See FIG. 2). Also, in case Kr/O₂ is 90%/10%, the oxygen atom density was measured by an appearance mass spectrometry. According to this method, it takes time to measure, but the absolute atom density, not the relative atom density as mentioned above, can be measured. As a result of the measurement, the absolute atom density of the oxygen atom was 2×10¹³ cm⁻³.

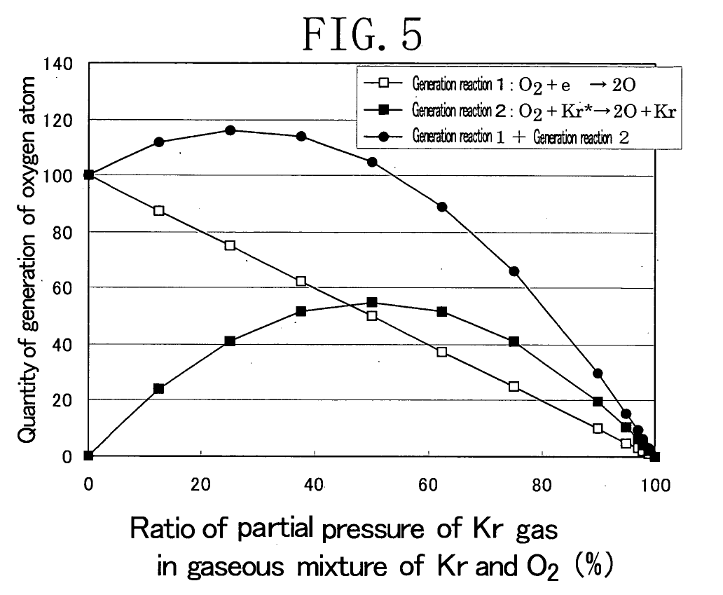

With respect to such a coincidence in tendency of the experimental data, a result of a numerical analysis on the atom density of oxygen is shown as a graph in FIG. 5. Generation of the oxygen atoms by collision of oxygen gas molecules and electrons (generation reaction 1, shown by white square marks (□)) linearly decreases with decrease in O₂ partial pressure. Also, generation of oxygen atoms by collision of oxygen gas molecules and Kr gas molecules (generation reaction 2, shown by black square marks (▪)) is the greatest when Kr/O₂ is 50%/50% and decreases with increase or decrease in Kr. The generation reactions 1 and 2 are shown by the following formulae.

[Formula 1]

O₂+e→2O Generation reaction 1:

O₂+Kr*→2O+Kr Generation reaction 2:

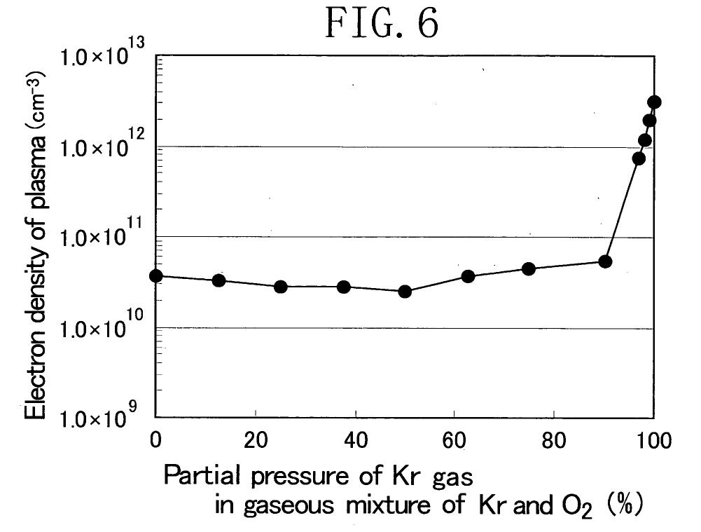

To analyze these generation reactions, the electron density in the plasma was measured with a Langmuir probe. The result of this is shown as a graph in FIG. 6. As seen from FIG. 6, when the partial pressure of Kr in the mixed gas of Kr and O₂ reaches 90% or over, the electron density in the plasma rapidly increases. Also, as a result of a measurement of the density of oxygen atoms, when the plasma electron density was 3×10¹¹ cm⁻³ or over, the density of oxygen atoms was 2×10¹³ cm⁻³ or over. Also, the electron density in the plasma is very high under the gaseous environment of only Kr, and when oxygen gas was introduced little by little into this plasma, it was found that oxygen atoms are generated and that the electron density in the plasma is lowered.

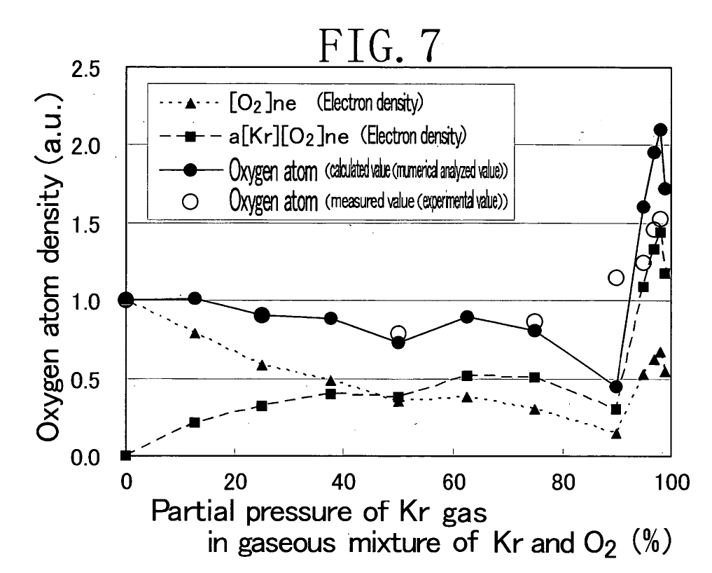

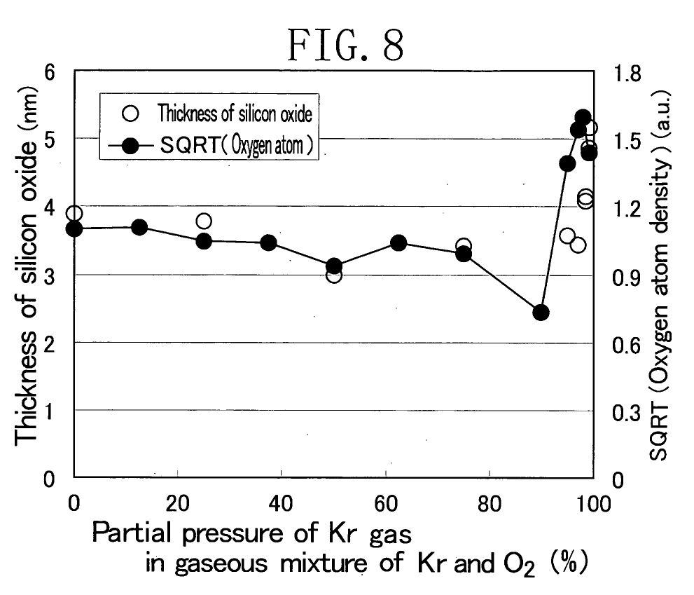

From the measurement result of the electron density in the plasma shown in FIG. 6 and the calculated value by the numerical analysis shown in FIG. 5, the graph of FIG. 7 is obtained. It is understood that the increase of the electron density in the plasma greatly influences the increase of the atom density of oxygen. According to a theory of oxidation reaction, as shown in FIG. 8, the thickness of a silicon oxide film in a so-called diffusion control condition wherein the oxygen atoms are diffused in a silicon oxide film generated by oxidation. And the thickness of the silicon film is shown by the square root of the number of oxygen atoms. As shown in FIG. 8, it is understood that the value of the numerical analysis coincides well with the value of the measured thickness of the silicon oxide film.

Thus, within the plasma having the electron density of 3×10¹¹ cm⁻³, it was found that the density of the oxygen atoms reaches 2×10¹³ cm⁻³ or over.

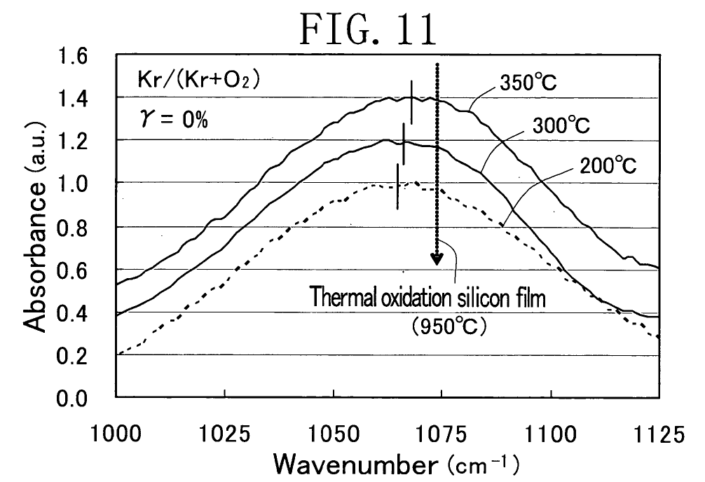

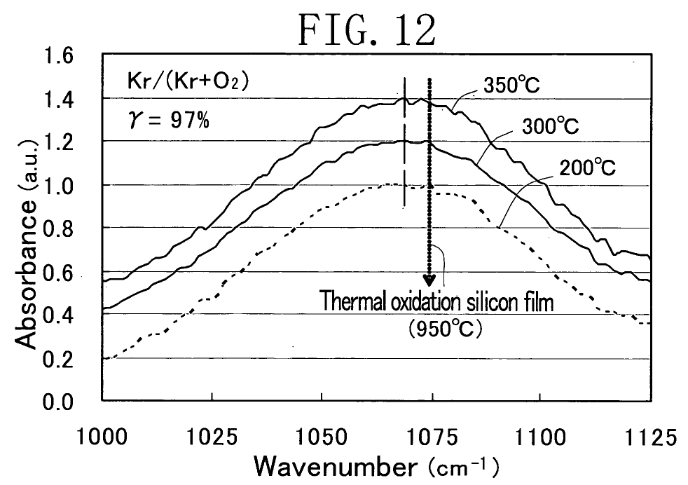

To analyze the characteristics of the plasma oxidation film of silicon, an infrared absorption spectrum of the plasma oxidation film was measured. FIG. 11 shows the measurement results of the infrared absorption spectrum of the plasma oxidation films which formed at various temperatures of the substrate and γ=O (%). The ratio γ shows the ratio of krypton to the mixed gas of krypton and oxygen (i.e., γ=Kr/(Kr+O₂)). Likewise, in FIG. 12 are shown the results of the infrared absorption spectrum of the plasma oxidation film prepared at various temperatures of the substrate at γ=97(%). The thickness of the sample plasma oxidation film used for the measurement is from 5 to 8 nm. As shown in FIG. 11, when O₂ plasma in which γ=0(%) was used, the peak wave number of TO phonon mode from the silicon oxide film is lowered respectively to 1069 cm⁻¹, 1066 cm⁻¹, 1064 cm⁻¹ as the temperature of the substrate was lowered to 350° C., 300° C., 200° C., As shown in FIG. 12, when the Kr/O₂ plasma in which γ=97(%) was used, the peak wave number of the TO phonon mode from the silicon oxide film was approximately a constant value (in the illustration 1070 cm⁻¹) and does not depend on the temperature of the substrate at least in the illustrated temperature range. The peak wave number of the TO phonon mode is, as shown in FIG. 12, is approximately the same as the peak wave number of the thermal oxidation silicon film at 950° C. This indicates that, when Kr/O₂ plasma is used, a fine oxidation film can be obtained even at a lower temperature.

Embodiment 2

By oxidizing the silicon layer 25 using the surface wave plasma in which Kr/O₂ is 97%/3% using the plasma processing unit 10 shown in FIG. 1, a silicon oxide film 41 of 4 nm thickness was formed on the surface of the silicon layer 25. Then, a silicon oxide film (SiO₂) 42 of 50 nm was deposited on the silicon oxide film 41 by a plasma enhanced chemical vapor growth method (PECVD). A chemical vapor deposition apparatus with an electro magnetic wave generator of a VHF band and a gaseous mixture with tetraethylorthosilicate (hereinafter to be called “TEOS”) was used for the deposition. An aluminum electrode was formed on the silicon oxide film 42 to produce a capacitor, and an interface state density was measured from the capacitance-voltage (C-V) characteristics.

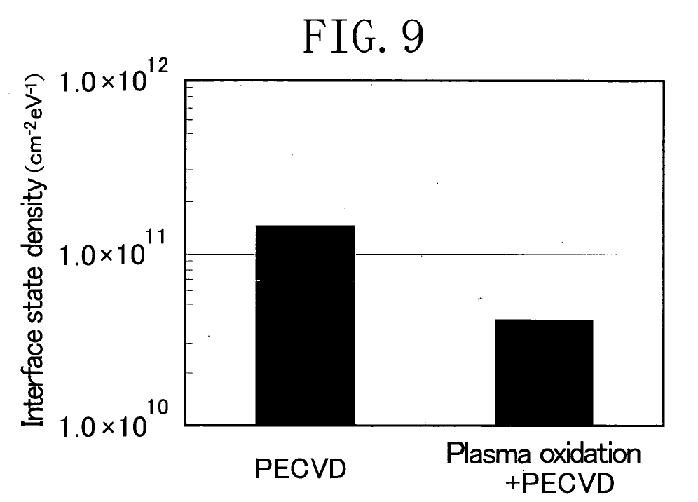

The result of the measurement is shown as a graph in FIG. 9. The interface state density was 4×10¹⁰ cm⁻² eV⁻¹. This value is smaller than the value 1.4×10¹¹ cm⁻² eV⁻¹ in case the silicon oxide film 42 was directly deposited by CVD method. The interfacial quality was improved. Next, a reliability test was conducted by applying the constant voltage of plus and minus 3 Mv/cm to the capacitor for thirty minutes at 150° C. In particular, when the minus voltage was applied, a flat band voltage changed. The flat band voltage in case of the silicon oxide film 41 of 4 nm, which is formed by plasma having an electron density of the above-mentioned 3×10¹¹ cm⁻³ or over, changed from −1.8 V to −1.4 V. This amount of change is smaller than that from −2.5 V to −1.4 V of the flat band voltage in case of no silicon oxide film 41 by the above-mentioned plasma, and the reliability was improved.

Embodiment 3

The silicon was oxidized in the plasma having only oxygen without using the above-mentioned rare gas to form a silicon oxide film.

Similarly to the embodiment 1, the plasma processing equipment 10 shown in FIG. 1 was used, and after an evacuation within the reaction chamber 22, oxygen gas was introduced into the reaction chamber 22 until the gas pressure reached, for example, 40 Pa, and the substrate 24 was heated at 300° C., a microwave of 2.45 GHz having the power of 3000 W was supplied into the reaction chamber 22. Thereby, plasma having the electron density of 3×10¹¹ cm⁻³ was generated, and an oxidation treatment was applied to the silicon layer 25. The time for the oxidation treatment of the silicon was four minutes.

The composition of the silicon oxide film formed by this silicon oxidation treatment was measured. The composition ratio of silicon and oxygen was 1:1.94. This silicon oxide film is a dielectric with excellent film composition.

Embodiment 4

Without using a rare gas, the frequency of the power supplier was raised, thereby increasing the electron density in the plasma. Similarly to embodiment 1, the plasma processing equipment 10 shown in FIG. 1 was used, and after evacuating the reaction chamber 22, the oxygen gas was introduced into the reaction chamber 22 until the gaseous pressure reached, for example, 40 Pa, and the substrate was heated at the 300° C., the frequency of the power supplier was raised from 2.45 GHz to 10 GHz, a microwave having the power of 1000 W was supplied into the reaction chamber 22, the plasma having the electron density of 3×10⁻¹¹ cm⁻³ was generated, and an oxidation treatment was applied to the silicon layer 25. The time for the silicon oxidation treatment was four minutes.

The composition ratio of silicon and oxygen in the silicon oxide film formed by this silicon oxidation treatment was 1:1.94.

Embodiment 5

This is an embodiment for forming a silicon nitride film. By using the plasma processing equipment 10 shown in FIG. 1, the power supply frequency of 2.45 GHz, Ar mixture ratio of mixture Ar/(Ar+N₂)=95% and the gas pressure 80 Pa, and the power of 1000 W were used to generate the surface wave plasma, a silicon nitride film is formed on the surface of the silicon layer 25. By this nitriding treatment of silicon, the composition ratio of silicon and nitrogen in the silicon nitride film was 3:3.84.

Embodiment 6

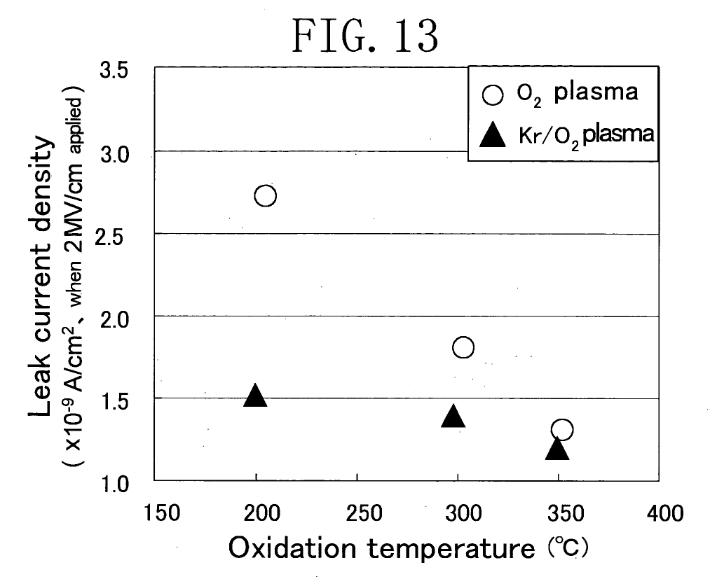

As regards the silicon oxide film, the relation between the oxidation temperature and leak current density was studied. FIG. 13 is a graph showing the relation between the oxidation temperature and leak current density (the current density when the voltage of 2 Mv/cm was applied), for a silicon oxide film formed by pure oxygen plasma and a silicon oxide film formed by Kr-mixed oxygen (Kr=97%) plasma. The thickness of the silicon oxide film was 4 nm. In case of the silicon oxide film by the Kr-mixed oxygen plasma, when the oxidation temperature lowered from 350° C. to 200° C., the leak current density was so small as 1.5×10⁻⁹ A/cm² or less, and hardly changed. On the other hand, in case of the silicon oxide film by the pure oxygen plasma, the leak current density increased as the oxidation temperature is lowered. The foregoing embodiment is not limited to only this state, though explained as being in a state of the surface wave plasma.

Various combinations are feasible for stacked films. In case of embodiment 2, after oxidizing the silicon surface with oxygen plasma, a silicon oxide film is formed by the PECVD method. Besides this, it is also possible to form a silicon nitride film by the PE CVD method after nitriding the silicon surface with nitrogen (N₂) plasma.

In place of the foregoing dielectric film, it is also possible to form a dielectric film containing a silicon oxynitride film having at least silicon oxide or at least silicon nitride having an ideal composition ratio as a dielectric film. In other words, it is possible to obtain a dielectric in which an SiO₂ layer is formed by plasma oxidation according to the method of embodiment 1 and in which Si₃N₄ is formed on the SiO₂ layer by plasma nitriding according to the method of embodiment 5. The order of formation may be reversed.

The foregoing substrate is a glass substrate or a plastic substrate. Alternatively, the substrate may be one wherein a silicon layer or a silicon compound layer is directly or indirectly formed on at least a part of the glass substrate or the plastic substrate, and wherein the dielectric film is formed on at least a part of the silicon layer or the silicon compound layer.

As the plastic substrate, it is possible to use one made of polyimide resin (the highest temperature: 275° C.), polyetherketone resin (hereinafter called “PEK”; the highest temperature: 250° C.), polyethersulphone resin (hereinafter called “PES”; the highest temperature: 230° C.), polyetherimide resin (hereinafter called “PEI”; the highest temperature: 200° C.), polyethylenenaphthalate resin (hereinafter called “PEN”; the highest temperature: 150° C.), or polyester resin (the highest temperature: 120° C.) such as polyethylenetelephthalate resin (hereinafter called “PET”).

In case of using the glass substrate, it is possible to adopt the highest temperature of about 600° C. in general as an environmental temperature in a production process and a temperature to be applied to the glass substrate. Also, in case of using the plastic substrate, it is possible to adopt the highest temperature for each above-mentioned resin as an environmental temperature in a production process and a temperature to be applied to the plastic substrate.

In the above-mentioned embodiments, it is possible to use in a coating layer of a lens by changing, for example, the whole of the above-mentioned silicon into a silicon oxide film which is a film having transparency. As regards the silicon oxide film, since the composition ratio of silicon and oxygen is an ideal composition ratio as mentioned above, the optical characteristic in a coating layer of a lens, for example, a refractive index becomes excellent.

Embodiment 7

By performing plasma nitriding to a silicon oxide film formed by plasma oxidation of the silicon layer 25 in plasma in which Kr/O₂ is 97%/3%, a silicon oxynitride film can be made. The above-mentioned dielectric film can apply to an insulating layer of a semiconductor device, for example, a gate insulating layer of a thin film transistor (hereinafter called “TFT”). Then, the leak current and interface characteristics in a semiconductor device is improved, thereby improving the electric characteristic of the semiconductor device. Also, by adopting the gate dielectric layer of silicon oxynitride film containing at least one of silicon oxide in which the composition ratio is Si:O₂=1:1.94 and silicon nitride in which the composition ratio is Si:N=3:3.84, the dielectric constant can be raised, whereby the initial electric characteristic of the TFT was kept with age, and reliability was improved.

Embodiment 8

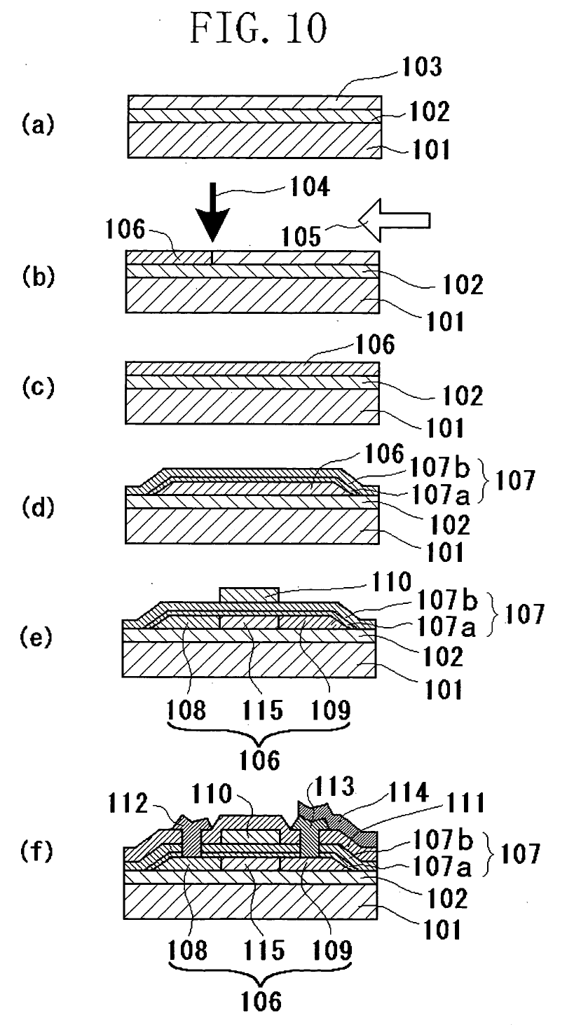

An example in which, as a substrate, one made of polyimide resin was used to produce a thin film transistor (hereinafter called “TFT”) is explained with reference to FIG. 10. In the example shown in FIG. 10, 200 nm thick silicon oxide layers 102 are respectively formed by the evaporation method or the sputtering method on the substrate 101 made of polyimide resin to improve heat endurance at the time of laser crystallization and to prevent gas emission from the resin.

In producing a semiconductor device, as shown in FIG. 10(a), after a base coat layer 102 and an amorphous silicon layer 103 are formed in this order on the substrate 101, the amorphous silicon layer 103 is treated for dehydrogenation. As shown in FIG. 10(b), while scanning the glass substrate 101 in the direction of an arrow 105, a broad area of the surface of the amorphous silicon layer 103 is irradiated by a laser beam. The amorphous silicon layer 103 in the area irradiated with the laser beam is, as shown in FIG. 10(c), crystallized into a polycrystal silicon layer 106.

After patterning the polycrystal silicon layer 106, a gate insulating layer 107 and a gate electrode 110 are formed on the polycrystal silicon layer 106 as shown in FIGS. 10(d) and (e). Then, with the gate electrode 110 as a mask, n-type or p-type impurities are injected into a part of the polycrystal silicon layer 106 through the gate insulating layer 107, and a source region 108 and a drain region 109 are formed in a part of the polycrystal silicon layer 106. The gate insulating layer 107, similarly to that explained in embodiment 2, after oxidizing the silicon layer 25 provided on the surface of the substrate 24 in plasma in which Kr/O₂ is 97%/3% and forming a 4 nm thick silicon oxide film 107a on the silicon layer 106, a silicon oxide film (SiO₂) 107b of 50 nm was formed on the silicon oxide film 107a by using a VHF-CVD apparatus with a gaseous mixture of TEOS and O₂.

Next, referring to FIG. 10(f), after activating impurities in a source region 108 and a drain region 109 by laser beam annealing, an interlayer insulating layer 111 was formed, contact holes are formed at the portions of the gate insulating layer 107 and the interlayer insulating layer 111 located above each of the source region 108 and the drain region 109, the source electrode 112 and the drain electrode 113 are formed for electric connection with the source region 108 and the drain region 109, and metal wiring 114 for transmitting an electric signal is formed.

By this process, a polycrystal silicon thin film transistor in which the current flowing in a channel region 115 between the source region 108 and drain region 109 is controlled by the voltage applied to the gate electrode 110, that is, the gate voltage can be obtained.

As regards an electron mobility, when there was no silicon oxide film formed by plasma having the electron density of 3×10¹¹ cm⁻³ or over, the electron mobility was 50 cm²/(V·S), while it was 80 cm²/(V·S) when there was the silicon oxide film by the plasma, resulting in improvement in the electron mobility. Also, a reliability test was conducted for two hours, making a source potential, a drain potential and a gate potential respectively 0 V, 5 V and 5 V. The variation of a threshold voltage of the TFT characteristic was 2.0 V when there was no silicon oxide film by the plasma, while it was 1.0 V when there was the silicon oxide film by the plasma was 1.0 V, so that a decrease in the variation was confirmed. This is because a nitride film or an oxynitride film of silicon having a composition ratio close to a stoichiometrical ideal composition ratio can be obtained by the present invention an oxide film under a low temperature environment. In the foregoing example, the plastic substrate was made of the polyimide resin, while the substrate made of polyetheretherketone resin, polyethersulfone resin, polyetherimide resin, polyethylenenaphthalate resin or polyester resin such as polyethylenetelephthalate resin can be used as the replacement of the polyimide resin.

What is claimed is:

1. A dielectric film formed directly or indirectly on at least a part of a glass substrate or a plastic substrate, comprising silicon oxide in a part at least in the direction of the film thickness, the composition ratio of silicon and oxygen being between 1:1.94 and 1:2 both inclusive.

2. A dielectric film formed directly or indirectly on at least a part of a glass substrate or a plastic substrate, comprising silicon nitride in a part at least in the direction of the film thickness, the composition ratio of silicon and nitrogen being between 3:3.84 and 3:4 both inclusive.

3. A dielectric film formed directly or indirectly on at least a part of a glass substrate or a plastic substrate, comprising silicon oxide in which the composition ratio of silicon and oxygen is between 1:1.94 and 1:2 both inclusive, or silicon oxynitride in which the composition ratio of silicon and nitrogen being between 3:3.84 and 3:4 both inclusive, in a part at least in the direction of the film thickness.

4. A dielectric film according to any one of claims 1 through 3, wherein a silicon layer or a silicon compound layer is formed directly or indirectly on at least a part of said glass substrate or said plastic substrate, and wherein said dielectric film is formed on at least a part of said silicon layer or said silicon compound layer.

5. A dielectric film according to any one of claims 1 through 3, wherein said plastic substrate is made of polyimide resin, polyetherketone resin, polyethersulfone resin, polyetherimide resin, polyethylenenaphthalate resin or polyester resin.

6. A method of forming a dielectric film according to any one of claims 1 through 3, comprising steps of preparing a substrate having in the surface of a silicon layer formed directly or indirectly at least on a part of said glass substrate or said plastic substrate; and processing the surface of said silicon layer in plasma having an electron density 3×10¹¹ cm⁻³ or over formed by exciting a gas composed of at least one element constituting said dielectric film.

7. A method of forming the dielectric film according to claim 6, wherein said gas is composed of an oxygen molecule, or a molecular nitrogen or an ammonia molecule.

8. A method of forming the dielectric film according to claim 6, wherein said gas further contains a gas composed of a rare gas element, and wherein the partial pressure of said gas composed of the rare gas element is 90% or over of the total pressure.

9. A method of forming a dielectric film according to claim 8, wherein said rare gas element is argon, or xenon or krypton.

10. A method of forming a dielectric film according to claim 6, wherein said gas is an oxygen molecule, said rare gas element is xenon, and the energy of a light generated from said plasma is 8.8 eV or less.

11. A method of forming a dielectric film according to claim 6, wherein a frequency of a power supplier for generating said plasma is 2.45 GHz or over.

12. A method of forming a dielectric film according to claim 6, wherein said glass substrate or said plastic substrate is heated at a temperature between 90° C. and 400° C. both inclusive.

13. A semiconductor device having a dielectric film formed on at least a part of a silicon layer formed directly or indirectly on at least a part of a glass substrate or a plastic substrate, said dielectric film comprising silicon oxide in which the composition ratio of silicon and oxygen is between 1:1.94 and 1:2 both inclusive in a part at least in the direction of the film thickness.

14. A semiconductor device having a dielectric film formed on at least a part of a silicon layer formed directly or indirectly on at least a part of a glass substrate or a plastic substrate, said dielectric film comprising silicon nitride in which the composition ratio of silicon and nitrogen is between 3:3.84 and 3:4 both inclusive in a part at least in the direction of the film thickness.

15. A semiconductor device having a dielectric film formed on at least a part of a silicon layer formed directly or indirectly on at least a part of a glass substrate or a plastic substrate, said dielectric film comprising silicon oxynitride having silicon oxide in which the composition ratio of silicon and oxygen is between 1:1.94 and 1:2 both inclusive in a part at least in the direction of the film thickness or silicon nitride in which the composition ratio of silicon and nitrogen is between 3:3.84 and 3:4 both inclusive in a part at least in the direction of the film thickness.

16. A semiconductor device according to any one of claims 13 through 15, wherein said dielectric film constitues a part of a gate dielectric layer relative to the direction of the thickness of the gate dielectric layer.

17. A semiconductor device according to any one of claims 13 through 15, wherein said plastic substrate is made of polyimide resin, polyetheretherketone resin, polyethersulfone resin, polyetherimide resin, polyethylenenaphthalate resin or polyester resin.

18. A method of producing a semiconductor device according to any one of claims 13 through 15, comprising steps of: preparing a substrate having a silicon layer formed directly or indirectly on at least a part of said glass substrate or said plastic substrate; and processing the surface of said silicon layer in plasma having an electron density of 3×10¹¹ cm⁻³ or over formed by exciting a gas composed of at least one element constituting said dielectric film.

19. A method of producing a semiconductor device according to claim 18, wherein said gas is composed of an oxygen molecule, or a molecular nitrogen or an ammonia molecule.

20. A method of producing the semiconductor device according to claim 18, wherein said gas further contains a gas composed of a rare gas element, and wherein the partial pressure of the rare gas element is 90% or over of the total pressure.

21. A method of producing the semiconductor device according to claim 20, wherein said rare gas element is argon, or xenon or krypton.

22. A method of producing a semiconductor device according to claim 20, wherein said gas is an oxygen molecule, said rare gas element is xenon, and the energy of a light generated from the plasma is 8.8 eV or less.

23. A method of producing the semiconductor device according to claim 18, wherein a frequency of a power supplier for generating said plasma is 2.45 GHz or over.

24. A method of producing the semiconductor device according to claim 18, wherein said glass substrate or said plastic substrate is heated at a temperature between 90° C. and 400° C., inclusive.

25. A method of producing the semiconductor device according to claim 18, wherein said dielectric film is a gate dielectric layer of a thin film transistor.
